(19) United States
(12) Patent Application Publication
(10) Pub. No.: US 2025/0218733 A1
(43) Pub. Date: Jul. 3, 2025

(54) SUBSTRATE PROCESSING APPARATUS

(71) Applicant: TES CO., LTD, Yongin-si (KR)

(72) Inventors: Woo-Young CHUNG, Yongin-si (KR); Jong-Wook KIM, Yongin-si (KR); Hwan-Hee LEE, Yongin-si (KR); Yong-Yi YIN, Yongin-si (KR)

(73) Assignee: TES CO., LTD, Yongin-si (KR)

(21) Appl. No.: 19/000,463

(22) Filed: Dec. 23, 2024

(30) Foreign Application Priority Data
Dec. 27, 2023 (KR) 10-2023-0192292

(51) Int. Cl. H01J 37/32; C23C 16/509; C23C 16/52

(52) U.S. Cl. CPC H01J 37/32449; C23C 16/5096; C23C 16/52; H01J 37/3211; H01J 2237/332

(57) ABSTRACT

A substrate processing apparatus includes a chamber, a dielectric window, an upper coil, and a gas distribution plate. The chamber provides a processing space for a substrate. The dielectric window is provided on an upper part of the chamber and maintains a pressure inside the chamber. The upper coil is provided on an upper part of the dielectric window and receives Radio Frequency (RF) power to generate plasma in the processing space. The gas distribution plate is provided on a lower part of the dielectric window and supplies main gas or reaction gas to the processing space. A flow space in which the main gas or the reaction gas flows is provided between the gas distribution plate and the dielectric window, and the main gas or the reaction gas is distributed through the flow space to be supplied to the processing space.

### CROSS-REFERENCE TO RELATED APPLICATIONS

A claim for priority under 35 U.S.C. § 119 is made to Korean Patent Application No. 10-2023-0192292 filed on Dec. 27, 2023, in the Korean Intellectual Property Office, the entire contents of which are hereby incorporated by reference.

### BACKGROUND OF THE INVENTION

### Field of the Invention

The present invention relates to a substrate processing apparatus, and more particularly to the substrate processing apparatus which is configured to deposit a hard mask thin film on a substrate using inductively coupled plasma, and is capable of adjusting a thickness or a shape of the thin film deposited on the substrate.

### Description of the Related Art

In general, a photolithography process is involved in manufacturing semiconductor devices, and in order to prevent the photoresist from collapsing due to a recent miniaturization process, a hard mask thin film is deposited on a substrate.

Such a hard mask thin film comprises an amorphous carbon layer, and conventionally, Capacitively Coupled Plasma (CCP) has been used, and recently, Inductively Coupled Plasma (ICP) has begun to be used.

Meanwhile, when the hard mask thin film is deposited on a top surface of the substrate as described above, it is necessary to maintain a uniform thickness of the thin film deposited on the substrate. In addition, in some cases, it may be necessary to adjust a shape of the thin film deposited on the substrate to be convex or concave.

### SUMMARY OF THE INVENTION

The present invention is contemplated to solve problems in the prior art mentioned above. Thus, it is an object of the present invention to provide a substrate processing apparatus capable of adjusting an average thickness and a shape of a thin film deposited on a substrate by adjusting an amount of process gas supplied from upper and side regions of a processing space in a chamber.

To solve the above problems, the present invention may provide a substrate processing apparatus comprising: a chamber configured to provide a processing space for a substrate; a dielectric window provided on an upper part of the chamber and configured to maintain a pressure inside the chamber; an upper coil provided on an upper part of the dielectric window, the upper coil being configured to receive Radio Frequency (RF) power and to generate plasma in the processing space; and a gas distribution plate provided on a lower part of the dielectric window and configured to supply main gas or reaction gas to the processing space, wherein a flow space in which the main gas or the reaction gas flows, is provided between the gas distribution plate and the dielectric window, and wherein the main gas or the reaction gas is distributed through the flow space and is supplied to the processing space located below.

Here, a recess which forms the flow space, may be provided to at least one of the gas distribution plate and the dielectric window.

Meanwhile, the substrate processing apparatus may further comprise a gas supply unit for supplying the main gas or the reaction gas in the processing space through a side wall of the chamber.

In this case, the gas supply unit may include: a gas supply channel provided along the side wall of the chamber; and a plurality of gas injection holes provided in the side wall of the chamber and connected to the gas supply channel to supply the main gas or the reaction gas toward the processing space.

Further, an injection angle of the main gas or the reaction gas supplied to the processing space may be adjusted by adjusting an injection angle of the gas injection hole with respect to the side wall of the chamber.

Meanwhile, a thickness and a shape of a thin film deposited on the substrate may be adjusted by adjusting amounts of the main gas and the reaction gas supplied through the gas distribution plate and the gas supply unit.

For example, an average thickness of the thin film on the substrate may be adjusted by adjusting the amount of the main gas supplied through the gas distribution plate and the gas supply unit.

Further, the shape of the thin film on the substrate may be adjusted by adjusting the amount of the reaction gas supplied through the gas distribution plate and the gas supply unit.

Details of examples or implementations will be described in the following with reference to the accompanying drawings. Other features will be apparent from the description and drawings, and from the claims.

### BRIEF DESCRIPTION OF THE DRAWINGS

The present invention will become more fully understood from the detailed description given below and the accompanying drawings, which are given by illustration only, and thus are not intended to limit the scope of the present Invention, wherein:

FIG. 1 is a side sectional view of a substrate processing apparatus according to one embodiment of the present invention;

FIG. 2 is a sectional view taken along to a line II-II of FIG. 1;

FIGS. 3A, 3B, and 3C are side sectional views each illustrating a first channel among a plurality of first gas supply channels and a first gas injection hole connected to the first channel; and

FIGS. 4A, 4B, and 4C are graphs illustrating each a thickness of a thin film deposited on a substrate by adjusting amounts of a first process gas and a second process gas supplied through a gas distribution plate and a gas supply unit.

### DETAILED DESCRIPTION OF THE PREFERRED EMBODIMENT

Description for the present invention will now be given in detail according to examples disclosed herein, with reference to the accompanying drawings.

For the sake of a brief description with reference to the drawings, the same or equivalent components may be provided with the same reference numbers, and description thereof will not be repeated. In the following, any conventional art which is well-known to one of ordinary skill in the relevant art has generally been omitted for the sake of brevity. The accompanying drawings are used to help easily understand various technical features and it should be understood that the examples presented herein are not limited by the accompanying drawings. As such, the present invention should be construed to extend to any alterations, equivalents, and substitutes in addition to those which are particularly set out in the accompanying drawings.

A singular representation may include a plural representation unless it represents a definitely different meaning from the context.

It will be understood that although the terms “first,” “second,” etc., may be used herein to describe various components, these components should not be limited by these terms. These terms are only used to distinguish one component from another component.

It should be understood that when a component is referred to as being “connected to” or “coupled to” another component, this component may be directly connected to or coupled to another component, or any intervening components may be present between the components. In contrast, when a component is referred to as being “directly connected to” or “directly coupled to” another component, there are no intervening components present.

Terms such as “comprise”, “include” or “have” are used herein and should be understood that they are intended to indicate an existence of several components, functions or steps, disclosed in the specification, and it is also understood that greater or fewer components, functions, or steps may likewise be utilized. Moreover, due to the same reasons, it is also understood that the present invention includes any combinations of features, numerals, steps, operations, components, parts and the like partially omitted from the related or involved features, numerals, steps, operations, components, and parts described using the aforementioned terms unless deviating from the intentions of the original disclosure.

Hereinafter, a configuration of a substrate processing apparatus according to embodiments of the present invention will be described in detail with reference to accompanying drawings.

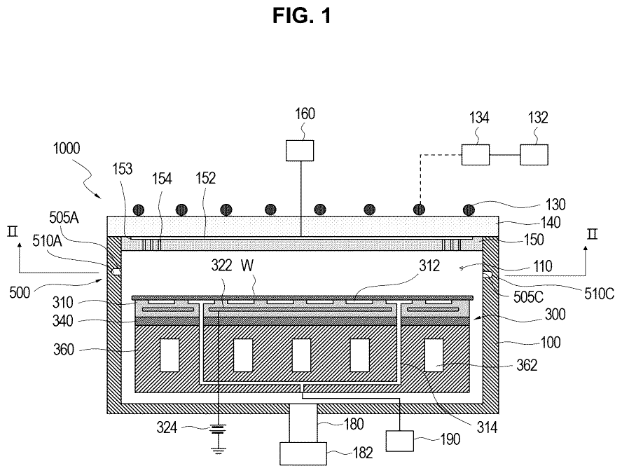

FIG. 1 is a side sectional view of a substrate processing apparatus 1000 according to one embodiment of the present invention.

Referring to FIG. 1, the substrate processing apparatus 1000 may include a chamber 100 providing a processing space 110 for a substrate W, a dielectric window 140 provided on an upper part of the chamber 100 to maintain a pressure inside the chamber 100, an upper coil 130 provided on the upper part of the chamber 100 and receiving Radio Frequency (RF) power from an RF power source 132 to generate plasma in the processing space 110, and a gas distribution plate 150 provided on a lower part of the dielectric window 140 to supply first process gas (or main gas) or second process gas (or reaction gas) to the processing space 110. Further, the substrate processing apparatus 1000 may include an electrostatic chuck 300 which is provided inside the chamber 100, and on which the substrate W is seated and fixed.

The substrate processing apparatus 1000 according to the present invention may correspond, for example, to a device for depositing a hard mask thin film on a top surface of the substrate W. The hard mask thin film may comprise an amorphous carbon layer and the like. Further, the substrate processing apparatus 1000 may use Inductively Coupled Plasma (ICP) to deposit the hard mask thin film as described above.

In this case, the chamber 100 may provide in an interior or inside thereof, the processing space 110 in which the substrate W is processed, and the plasma is generated.

On the upper part of the chamber 100, the upper coil 130 may be provided, which may receive power from the RF power source 132. For example, the RF power source 132 may provide the power tuned by a first matcher (or matching network) 134 to the upper coil 130. In this case, the upper coil 130 may generate the plasma within the processing space 110.

On the other hand, the upper part of the chamber 100 may be provided with the dielectric window 140 which maintains the pressure inside the chamber 100 and further allows energy generated by the upper coil 130 to pass therethrough. The upper coil 130 may be provided on an upper part of the window 140.

Further, the lower part of the window 140 may be provided with the gas distribution plate 150 for supplying the first process gas or the second process gas to the processing space 110. The gas distribution plate 150 may be provided with a plurality of supply holes 154 for supplying the first process gas or the second process gas. The gas distribution plate 150 may be made of the same material as the dielectric window 140, for example, ceramic material.

Specifically, a flow space 152 in which the first process gas or the second process gas flows, may be provided between the gas distribution plate 150 and the dielectric window 140. That is, the first process gas or the second process gas supplied from a process gas source 160 may be diffused and distributed through the flow space 152 and may be supplied to the processing space 110 below via the supply holes 154 of the gas distribution plate 150.

In this case, a recess 153 that forms the flow space 152 may be formed in at least one of the gas distribution plate 150 and the dielectric window 140. In FIG. 1, the recess 153 is shown as being formed on an upper (or top) surface of the gas distribution plate 150, but it is not limited thereto. That is, it may also be possible for a recess to be formed on a lower surface of the dielectric window 140, or for recesses to be formed on both of the dielectric window 140 and the gas distribution plate 150, respectively.

Accordingly, the process gas supplied from the process gas source 160 may be diffused and distributed in the flow space 152 and may be then supplied to the processing space 110 through the supply hole 154 of the gas distribution plate 150. Although only one process gas source 160 is shown in FIG. 1, it is not limited thereto. For example, if the number or type of the process gas increases, the number of the process gas supply source may also increase in correspondence with the number or type of the process gas.

Meanwhile, the chamber 100 may be provided with an exhaust channel 180 for exhausting gases or by-products or the like inside the processing space 110, and the exhaust channel 180 may be provided with an exhaust pump 182. The exhaust channel 180 may be provided with a pressure control valve (not shown). In this case, the exhaust pump 182 may comprise, for example, a turbo molecular pump. By using the turbo molecular pump, a low process pressure inside the chamber 100 may be achieved such that a mean free path of ions is increased to reduce energy losses due to collisions of ions.

The electrostatic chuck 300 on which the substrate W is rested, may be provided in the interior of the chamber 100. The electrostatic chuck 300 may include a chuck electrode 322 that holds the substrate W by electrostatic force.

The electrostatic chuck 300 may include an upper plate 310 made of a dielectric, a heating plate 340 provided on a lower part of the upper plate 310 to heat the substrate W, and a support plate 360 provided on a lower part of the heating plate 340.

The upper plate 310 may have a flat plate member comprising the dielectric. The upper plate 310 may comprise at least one of, but not limited to, ceramics such as, for example, Aluminum Oxide (Alumina: Al₂O₃), Aluminum Nitride, Silicon Carbide, Silicon Nitride, and Yttrium Oxide (Yttria: Y₂O₃).

The chuck electrode 322 may be disposed within the upper plate 310. The chuck electrode 322 may be electrically connected to a direct current power source 324. When a direct current voltage from the direct current power source 324 is applied to the chuck electrode 322, the electrostatic force is generated between the chuck electrode 322 and the substrate W. By such electrostatic force, the substrate W is held on the upper (or top) surface of the upper plate 310.

Meanwhile, the lower part of the upper plate 310 may be provided with the heating plate 340 for heating the substrate W. The heating plate 340 may be configured to have, for example, an embedded (or built-in) film heater (not shown). However, the film heater is described by way of example and The heating plate 340 may be configured in various mechanism. bonding layers (not shown) may be provided to the upper and lower parts of the heating plate 340.

Further, the lower part of the heating plate 340 may be provided with the support plate 360. The support plate 360 may be made of metal, for example, Aluminum or the like. Although the support plate 360 is shown as a single member in FIG. 1, the support plate 360 is not limited thereto and may include two or more members.

The support plate 360 may be provided with a heat transfer channel 362 through which heat transfer fluid flows. The temperature of the support plate 360 may be regulated by the heat transfer fluid flowing through the heat transfer channel 362.

Meanwhile, the upper plate 310 may be formed with a plurality of grooves 312, and the plurality of grooves 312 may be distributed on the upper surface of the upper plate 310.

In this case, a gas channel 314 may be formed at the electrostatic chuck 300 to penetrate through the electrostatic chuck 300 and to be connected to the grooves 312. That is, the gas channel 314 may pass through the support plate 360, the heating plate 340, and the upper plate 310 from a bottom of the electrostatic chuck 314 and then may be connected to the grooves 312.

A cooling gas, such as Helium (He) or the like, may be supplied from a cooling gas source 190 via the gas channel 314, and then may be supplied toward the bottom surface of the substrate W via the groove 312, so as to cool the substrate W.

In particular, when the substrate W is fixed and retained on the upper surface of the upper plate 310 by the chuck electrode 322, the cooling efficiency by the cooling gas supplied through the groove 312 may be increased. In addition, it may be possible to prevent the temperature rise of the substrate W caused by the ions in the processing space 110 which move toward and impinge on the substrate W by the bias electrode 332.

Meanwhile, when the hard mask thin film is deposited on the top surface of the substrate W, the substrate processing apparatus 1000 may need adjust a thickness of the thin film, and especially in some cases, may need to vary the thickness of the thin film according to areas of the substrate W. In order to adjust the thickness of the thin film deposited on the substrate W as such, the substrate processing apparatus 1000 may further include a gas supply unit 500 for supplying the first process gas (or the main gas) or the second process gas (or the reaction gas) to the processing space 110 through a side wall of the chamber 100. That is, the gas supply unit 500 may supply the first process gas or the second process gas from a side region (or area) of the processing space 110.

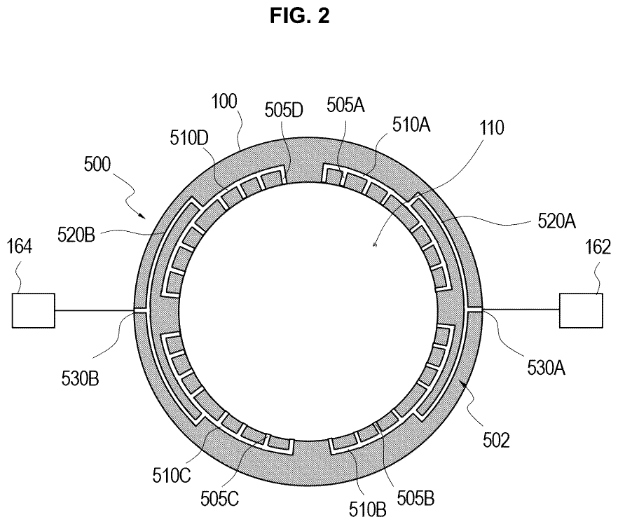

FIG. 2 is a sectional view taken along line II-II in FIG. 1. In FIG. 2, only the gas supply unit 500 and the chamber 100 are shown for simplicity of illustration.

Referring to FIG. 1 and FIG. 2, the gas supply unit 500 may include a gas supply channel 502 provided along the side wall of the chamber 100 and a plurality of gas injection holes 505A, 505B, 505C, 505D provided in the side wall of the chamber 100 and connected to the gas supply channel 502 to supply the first process gas or the second process gas toward the processing space 110.

In this case, the gas supply channel 502 may be formed by passing through the side wall of the chamber 100. For example, the gas supply channel 502 may include first gas supply channels 510A, 510B, 510C, 510D connected to the plurality of gas injection holes 505A, 505B, 505C, 505D, and second gas supply channels 520A, 520B connecting the first gas supply channels 510A, 510B, 510C, 510D to gas inlets 530A, 530B which communicate with the outside of the chamber 100.

While the first gas supply channels 510A, 510B, 510C, 510D are shown in FIG. 2 as including four channels, such first gas supply channels are only an example and may be modified to include any proper number of channels.

Further, the first gas supply channels 510A, 510B, 510C, 510D may be formed by passing through the side walls of the chamber 100. Moreover, as shown in FIG. 2, the plurality of first gas supply channels 510A, 510B, 510C, 510D may all have the same length, or alternatively, although not shown in the drawings, at least one of the plurality of first gas supply channels 510A, 510B, 510C, 510D may have a different length.

Each of the second gas supply channels 520A, 520B may be connected to a set including at least two of the first gas supply channels 510A, 510B, 510C, 510D. In this case, the second gas supply channels 520A, 520B may be disposed and formed on the outer side of the first gas supply channels 510A, 510B, 510C, 510D, i.e., on the outer side of the side wall of the chamber 100.

Further, as shown in the FIG. 2, a first channel 520A of the second gas supply channels may be connected to two first gas supply channels 510A, 510B, and a second channel 520B of the second gas supply channels may likewise be connected to the remaining two first gas supply channels 510C, 510D. The number of first gas supply channels 510A, 510B, 510C, 510D connected to each of the second gas supply channels 520A, 520B may be adaptively modified.

The second gas supply channels 520A, 520B may be connected to the gas inlets 530A, 530B communicating with the outside of the chamber 100, respectively. The gas inlets 530A, 530B may include a first inlet 530A connected to the first channel 520A of the second gas supply channels, and a second inlet 530B connected to the second channel 520B of the second gas supply channels. Alternatively, although not shown in the FIG. 2, the gas supply portion 500 may include a single gas inlet which is connected to both the first and second channels 520A, 520B of the second gas supply channels.

In the gas supply unit 500, process gas sources 162, 164 may be connected to the gas inlets 530A, 530B, respectively to supply the first process gas or the second process gas, and then the first process gas or the second process gas may be supplied to the processing space 110 via the second gas supply channels 520A, 520B, the first gas supply channels 510A, 510B, 510C, 510D and the gas injection holes 505A, 505B, 505C, 505D. Meanwhile, other than the process gas sources 162, 164, any additional process gas sources may be provided, depending on the number or type of process gas supplied via the gas supply unit 500. Further, the second process gas may be different from, or the same as, the first process gas.

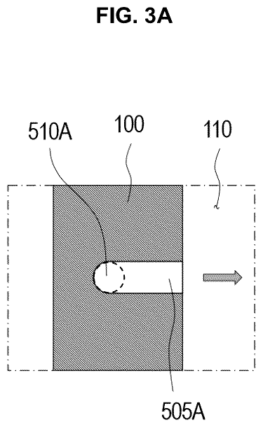

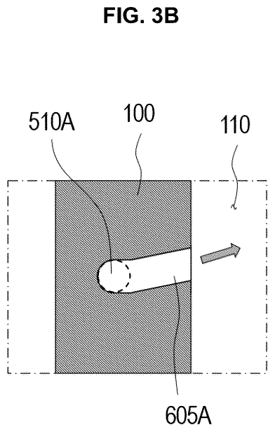

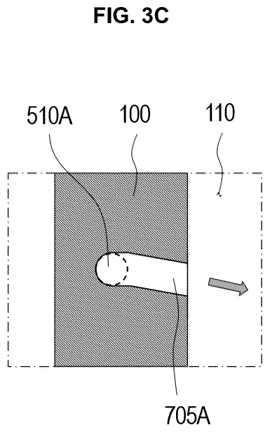

Meanwhile, FIGS. 3A, 3B, and 3C are side sectional views illustrating a first channel 510A among the plurality of first gas supply channels 510A, 510B, 510C, 510D and first gas injection holes 505A, 605A, 705A connected to the first channel 510A.

Referring to FIGS. 3A, 3B, and 3C, the substrate processing apparatus 1000 may adjust injection angles of the first gas injection holes 505A, 605A, 705A with respect to the side wall of the chamber 100 to adjust injection angles of the first process gas or the second process gas supplied to the processing space 110.

For example, the first gas injection hole 505A according to FIG. 3A may be formed in a direction perpendicular or normal to the side wall of the chamber 100, such that the first process gas or the second process gas injected through the first gas injection hole 505A is also supplied to the processing space 110 along the direction perpendicular to the side wall of the chamber 100 as indicated by the arrow.

Alternatively, referring to FIG. 3B, the first gas injection hole 605A may be inclined or oriented toward an upper region of the processing space 110. Accordingly, the first process gas or the second process gas injected through the first gas injection hole 605A may also be supplied toward the upper region of the processing space 110 as indicated by the arrow.

In contrast, referring to FIG. 3C, the first gas injection hole 705A may be inclined or oriented toward a lower region of the processing space 110. Accordingly, the first process gas or the second process gas injected through the first gas injection hole 705A may also be supplied toward the lower region of the processing space 110 as indicated by the arrow.

Although only the first gas injection holes 505A, 605A, 705A are shown in FIG. 3, other gas injection holes 505B, 505C, 505D may likewise be inclined with respect to the side walls of the chamber 100 to adjust the injection angles of the first process gas or the second process gas supplied to the processing space 110. In this case, the plurality of gas injection holes 505A, 505B, 505C, 505D may all be formed inclined in the same direction and at the same angle with respect to the side wall of the chamber 100, or alternatively, at least some of the plurality of gas injection holes 505A, 505B, 505C, 505D may be formed in different directions or at different angles with respect to the side wall of the chamber 100.

Meanwhile, inventors of the present invention have conducted an experiment to deposit the hard mask thins film comprising the amorphous carbon film on the top surface of the substrate W using the substrate processing apparatus 1000 according to FIG. 1 as described above.

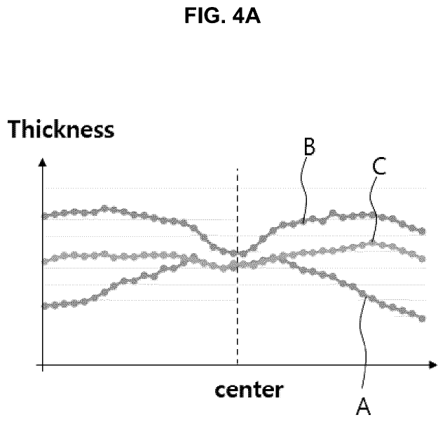

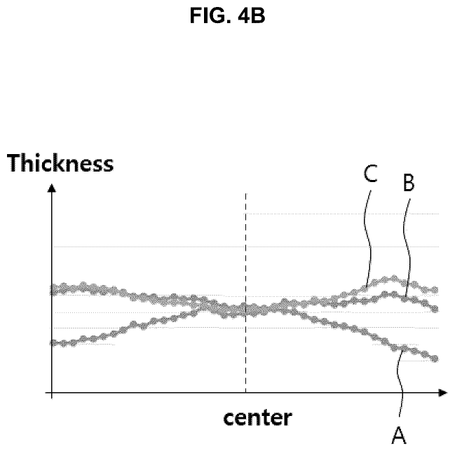

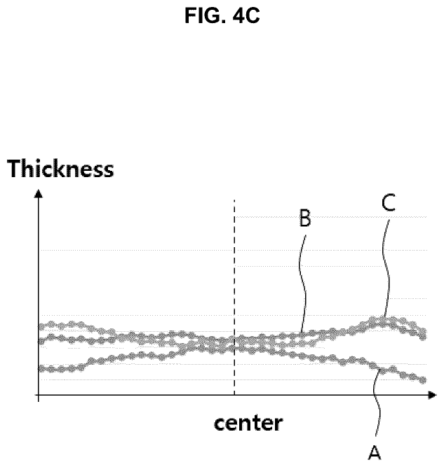

FIGS. 4A, 4B, and 4C are graphs each illustrating a thickness of the thin film deposited on the substrate W by adjusting the amounts of the first process gas and the second process gas supplied through the gas distribution plate 150 and the gas supply unit 500. In FIGS. 4A, 4B, and 4C, a horizontal axis indicates a distance from a center to an edge of the substrate W, and a vertical axis indicates the thickness of the thin film. Also, in FIGS. 4A, 4B, and 4C, Acetylene (C₂H₂) was used as the main gas, Hydrogen (H₂) was used as the reaction gas, and Argon (Ar) was supplied as the inert gas.

FIG. 4A illustrates a thickness distribution of the thin film deposited on the substrate W when Acetylene is supplied as the first process gas only through the gas distribution plate 150 (or Acetylene is supplied only from the upper region of the processing space 110), and Hydrogen is supplied via the gas distribution plate 150 and the gas supply unit 500. Argon as the inert gas is supplied only through the gas distribution plate 150.

In of FIGS. 4A, 4B, and 4C, ‘A’ lines represent a case where Hydrogen is supplied only through the gas distribution plate 150 (or where Hydrogen is supplied only from the upper region of the processing space 110), ‘B’ lines represent a case where Hydrogen is supplied in the equal or same amounts through the gas distribution plate 150 and the gas supply unit 500, respectively (or where Hydrogen is supplied in the equal or same amounts from the upper and side regions of the processing space 110, respectively), and ‘C’ lines represent a case where Hydrogen is supplied only through the gas supply unit 500 (or where Hydrogen is supplied only from the side region of the processing space 110).

Referring to FIG. 4A, it can be observed that when Hydrogen is supplied only through the gas distribution plate 150 (‘A’ line), a thin film of a convex shape is formed on a center portion of the substrate W. Further, it can be observed that when the same amounts of Hydrogen are supplied through the gas distribution plate 150 and the gas supply unit 500, respectively (‘B’ line), a thin film of a concave shape is formed on the center portion of the substrate W. Moreover, it can be observed that when Hydrogen is supplied only through the gas supply unit 500 (‘C’ line), a thin film with a generally uniform thickness is deposited on the substrate W.

Alternatively, FIG. 4B illustrates a thickness distribution of the thin film deposited on the substrate W when the same amounts of Acetylene are supplied through the gas distribution plate 150 and gas supply unit 500, respectively (or the same amounts of Acetylene are supplied from the upper and side regions of the processing space 110, respectively), and Hydrogen is supplied through the gas distribution plate 150 and gas supply unit 500. Argon as the inert gas, is supplied only through the gas distribution plate 150.

Referring to FIG. 4B, it can be observed that when Hydrogen is supplied only through the gas distribution plate 150 (‘A’ line), a thin film of a convex shape is formed on the center portion of the substrate W. Further, it can be observed that when the same amounts of Hydrogen are supplied through the gas distribution plate 150 and the gas supply unit 500, respectively (‘B’ line), a thin film with a generally uniform thickness is deposited on the substrate W. Moreover, it can be observed that when Hydrogen is supplied only through the gas supply unit 500 (‘C’ line), a thin film of a concave shape is formed on the center portion of the substrate W.

Alternatively, FIG. 4C illustrates a thickness distribution of the thin film deposited on the substrate W when Acetylene is supplied only through the gas supply unit 500 (or Acetylene is supplied only from the side region of the processing space 110), and Hydrogen is supplied through the gas distribution plate 150 and the gas supply unit 500. Argon, as the inert gas, is supplied only through the gas distribution plate 150.

Referring to FIG. 4C, it can be observed that when Hydrogen is supplied only through the gas distribution plate 150 (‘A’ line), a thin film of a convex shape is formed on the center portion of the substrate W. Further, it can be observed that when the same amounts of Hydrogen are supplied through the gas distribution plate 150 and the gas supply unit 500, respectively (‘B’ line), a thin film with a generally uniform thickness is deposited on the substrate W. Moreover, it can be observed that when Hydrogen is supplied only through the gas supply unit 500 (‘C’ line), a thin film of a roughly concave shape is formed on the center portion of the substrate W.

Meanwhile, considering FIGS. 4A, 4B, and 4C altogether, it can be confirmed that the thickness of the thin film deposited on the substrate W becomes thinner on average when proceeding from FIG. 4A to FIG. 4B then to FIG. 4C.

That is, it can be noted that the average thickness of the thin film on the substrate W is thickest when Acetylene corresponding to the first process gas is supplied only from the gas distribution plate 150 (or Acetylene corresponding to the first process gas is supplied only from the upper region of the processing space 110).

In contrast, it can be noted that the average thickness of the thin film of the substrate W is thinnest when Acetylene corresponding to the first process gas is supplied only through the gas supply unit 500 (or Acetylene corresponding to the first process gas is supplied only from the side region of the processing space 110).

Consequently, the experiments of the inventors have confirmed that the average thickness of the thin film of the substrate W can be controlled or adjusted by controlling or adjusting the amounts of the first process gas (or main gas) supplied through the gas distribution plate 150 and the gas supply unit 500 (or the amounts of the first process gas supplied through the upper and side regions of the processing space 110).

Further, the experiments of the inventors have confirmed that the convex shape and concave shape of the thin film on the substrate W can be adjusted or controlled by adjusting or controlling the amounts of the second process gas (or reaction gas) supplied through the gas distribution plate 150 and the gas supply unit 500 (or the amounts of the second process gas supplied through the upper and side regions of the processing space 110).

The substrate processing apparatus according to the present invention has the technical advantages as follows.

According to the present invention with the configuration described above, the average thickness and the shape of the thin film deposited on the substrate can be adjusted by adjusting the amounts of process gas supplied from the upper and side regions of the processing space inside the chamber.

Although a number of examples have been described, it should be understood that other modifications and implementations can be devised by those skilled in the art that will fall within the spirit and scope of the principles of the present invention. More particularly, various variations and modifications in the structure or the configuration are possible within the scope of the disclosure, the drawings, and the appended claims. In addition to variations and modifications in the configuration, alternative uses will also be apparent to those skilled in the art.

What is claimed is:

1. A substrate processing apparatus comprising:
a chamber configured to provide a processing space for a substrate;
a dielectric window provided on an upper part of the chamber and configured to maintain a pressure inside the chamber;
an upper coil provided on an upper part of the dielectric window, the upper coil being configured to receive Radio Frequency (RF) power and to generate plasma in the processing space; and
a gas distribution plate provided on a lower part of the dielectric window and configured to supply main gas or reaction gas to the processing space,
wherein a flow space in which the main gas or the reaction gas flows, is provided between the gas distribution plate and the dielectric window, and
wherein the main gas or the reaction gas is distributed through the flow space and is supplied to the processing space located below.

2. The substrate processing apparatus of claim 1, wherein a recess which forms the flow space, is provided to at least one of the gas distribution plate and the dielectric window.

3. The substrate processing apparatus of claim 1, further comprising a gas supply unit for supplying the main gas or the reaction gas in the processing space through a side wall of the chamber.

4. The substrate processing apparatus of claim 3, wherein the gas supply unit includes:
a gas supply channel provided along the side wall of the chamber; and
a plurality of gas injection holes provided in the side wall of the chamber and connected to the gas supply channel to supply the main gas or the reaction gas toward the processing space.

5. The substrate processing apparatus of claim 4, wherein an injection angle of the main gas or the reaction gas supplied to the processing space is adjusted by adjusting an injection angle of the gas injection hole with respect to the side wall of the chamber.

6. The substrate processing apparatus of claim 3, wherein a thickness and a shape of a thin film deposited on the substrate is adjusted by adjusting amounts of the main gas and the reaction gas supplied through the gas distribution plate and the gas supply unit.

7. The substrate processing apparatus of claim 6, wherein an average thickness of the thin film on the substrate is adjusted by adjusting the amount of the main gas supplied through the gas distribution plate and the gas supply unit.

8. The substrate processing apparatus of claim 6, wherein the shape of the thin film on the substrate is adjusted by adjusting the amount of the reaction gas supplied through the gas distribution plate and the gas supply unit.
